(19) United States
(12) Patent Application Publication
(10) Pub. No.: US 2026/0230743 A1
(43) Pub. Date: Aug. 6, 2026

(54) MEMS with Reduced Acoustic Impedance

(71) Applicant: Fraunhofer-Gesellschaft zur Förderung der angewandten Forschung e.V., München (DE)

(72) Inventors: Anton MELNIKOV, Dresden (DE); Bert KAISER, Dresden (DE); Sergiu LANGA, Dresden (DE)

(21) Appl. No.: 19/630,724

(22) Filed: Mar. 27, 2026

Related U.S. Application Data
(63) Continuation of application No. PCT/EP2024/078012, filed on Oct. 4, 2024.

(30) Foreign Application Priority Data
Oct. 5, 2023 (DE) 10 2023 209 767.2

(51) Int. Cl. H04R 1/28; B81B 1/00; B81C 1/00; H04R 31/00

(52) U.S. Cl. CPC H04R 1/2803; B81B 1/004; B81C 1/00071; H04R 31/00; B81B 2201/0257; B81B 2203/0338; B81B 2203/0376; B81C 2201/0132; H04R 2201/003

(57) ABSTRACT

A MEMS with a fluidic channel in at least one MEMS layer is provided. The fluidic channel is configured to provide a fluidic connection between a first channel side and a second channel side. A side-wall structure of the fluidic channel includes a scallop arrangement, wherein the acoustic channel includes an effective acoustic channel width due to the scallop arrangement, the acoustic channel width being enlarged when compared to a nominal channel width.

### CROSS-REFERENCES TO RELATED APPLICATIONS

This application is a continuation of copending International Application No. PCT/EP2024/078012, filed October 4, 2024, which is incorporated herein by reference in its entirety, and additionally claims priority from German Application No. DE 10 2023 209 767.2, filed October 5, 2023, which is incorporated herein by reference in its entirety.

### BACKGROUND OF THE INVENTION

The present invention relates to a MEMS with a fluidic channel that comprises an enlarged effective acoustic channel width due to a scallop arrangement and, thus, a reduced acoustic impedance. The present invention further relates to an apparatus, in particular a MEMS, for reducing acoustic impedances in a channel through which a fluid flows.

MEMS can be manufactured and used for different technical purposes. Some of these purposes relate to sound transducer systems, such as microphones or loudspeakers. Such MEMS sound transducer systems may have a fluid-displacing element, such as a diaphragm that is typically moved in an out-of-plane manner. Other configurations relate to an in-plane movement of a fluid-displacing element, wherein different concepts to this end are known. For example, in addition to elements that are formed to be active and that execute a movement in the plane by applying a control signal, other principles of deflection may also be implemented.

From WO 2021/223886 A1, a system is known in which a movable structure that is provided to interact with the fluid is displaced by a force generated on a different MEMS plane.

From WO 2022/117197 A1, a concept is known in which a deflecting force is generated by means of electrodes disposed opposite of the movable element to generate a force directed out of plane, which results in to an in-plane deflection of the movable element.

Such MEMS have in common that an operative surface for interacting with the fluid during manufacturing the MEMS is typically generated by etching along a depth direction in a wafer.

In CN 111243951 A, a method for deep-etching silicon is described. The same aims to manufacture the walls to be as smooth as possible and to prevent an undercut of the walls.

In JP 2007-311584 A, a deep opening having a vertical shape is formed in a semiconductor substrate using the Bosch process. The goal of this reference is, among other things, to manufacture the walls to be as smooth as possible.

US 2016/144365 A1 describes a method for increasing the scallop effect as the depth of the opening increases in order to achieve a negative side-wall angle in a MEMS.

US 2020/048080 A1 describes a method for manufacturing MEMS microphones using the Bosch method. With this method, a cavity hole is formed which is deeper than 100 µm. The wall of the cavity comprises a scallop structure.

MEMS with a fluidic channel that comprises a low fluidic impedance would be desirable.

### SUMMARY

According to an embodiment, MEMS with a fluidic channel in at least one MEMS layer are configured to provide a fluidic connection between a first channel side and a second channel side; wherein a side-wall structure of the fluidic channel comprises a scallop arrangement, wherein the fluidic channel comprises, due to the scallop arrangement, an effective acoustic channel width that is enlarged when compared to a nominal channel width.

According to another embodiment, a method for manufacturing a MEMS may have the step of generating a fluidic channel in at least one MEMS layer to provide a fluidic connection between a first channel side and a second channel side; so that a side-wall structure of the fluidic channel comprises a scallop arrangement, wherein the fluidic channel comprises, due to the scallop arrangement, an effective acoustic channel width that is enlarged when compared to a nominal channel width.

According to the invention, it was found that the use of smooth walls of a channel through which a fluid flows in the conventional technology is disadvantageous, since the same lead to an increase of acoustic impedances.

A core idea of the present invention is based on the finding that by using a scallop arrangement with a scallop structure, an effective acoustic channel width may be enlarged when compared to a nominal channel width. Enlarging the effective acoustic channel width leads to a reduction of the fluidic impedance, which is particularly advantageous for MEMS sound transducers.

According to an embodiment, a MEMS comprises a fluidic channel in at least one MEMS layer. The fluidic channel is configured to provide a fluidic connection between a first channel side and a second channel side. A side-wall structure of the fluidic channel comprises a scallop arrangement, wherein the acoustic channel comprises an effective acoustic channel width due to the scallop arrangement, the acoustic channel width being enlarged when compared to a nominal channel width, such as in the case of straight or perpendicular channel walls. The reduced acoustic impedance is advantageous for the acoustic quality.

According to an embodiment, a fluidic impedance of the fluidic channel is reduced when compared to a fluidic channel with a constant channel width corresponding to the nominal channel width.

According to an embodiment, the fluidic channel extends along a channel direction. At least one scallop structure of the scallop arrangement extends along the channel direction with a scallop height of at least 200 nm and/or perpendicular to the channel direction with a scallop depth of at least 100 nm when compared to the nominal channel width in the MEMS layer. These distinct scallop structures enable a precise definition of the acoustic impedance.

According to an embodiment, the MEMS comprises a movable element that is disposed in parallel to a MEMS plane and configured to interact with a fluid in order to cause a fluidic flow in the fluidic channel, wherein a movement of the movable element and a movement of the fluid through the fluidic channel are causally related. This enables reducing the acoustic impedance already at the location where the fluidic movement is created.

According to an embodiment, the fluidic channel is partially formed by a side-wall structure of the movable element that is disposed perpendicular to the MEMS plane.

According to an embodiment, the fluidic channel is a first fluidic channel, and the movable element comprises a first main side that is part of the first fluidic channel, such as a side wall of the fluidic channel. An opposite second main side of the movable element is part of a second fluidic channel, wherein, along a corresponding direction in parallel to the first fluidic channel, a monotonously increasing scallop height of a first multitude of scallop structures is disposed on the first main side and a monotonously decreasing scallop height of a second multitude of scallop structures is disposed on the second main side. Such a side-specific implementation of scallop structures may, for example, enable the reduction of acoustic impedances for a respective fluid stream direction.

According to an embodiment, the fluidic channel is configured for providing a fluid profile at base points of the scallop structure similar to a plane Poiseuille flow. At vertex areas of the scallop structure, the fluidic channel provides a flow with a reversal in flow direction. This enables local impedance-matching effects that reduce the total impedance of the fluidic channel.

According to an embodiment, the nominal channel width is variable over a course of the fluidic channel. In this respect, the scallop structure may provide a modulation of the variable nominal channel width. This enables obtaining an additional degree of freedom to influence the fluidic attenuation. For example, in addition to smaller scallops that may be limited in size (small period), because they are, for example, generated to be intrinsic by a Bosch etching, scallops with a larger period are arranged for a further modulation of the channel width.

According to an embodiment, the nominal channel width is periodically variable over the course of the fluidic channel.

According to an embodiment, the MEMS comprises a multitude of scallop structures, wherein a first pair of neighboring scallop structures comprises a different distance from vertex areas of the scallop structures than a second pair of neighboring scallop structures. This enables the fluidic impedance to be advantageously influenced locally.

According to an embodiment, the multitude of scallop structures comprise, along a course of the fluidic channel, mutually differing positions of base points along a channel width of the fluidic channel. This also achieves a good local adjustability.

According to an embodiment, the scallop arrangement comprises a multitude of scallop structures, wherein the fluidic channel extends along a channel direction and the multitude of scallop structures comprise a scallop height that varies monotonously, at least in portions, along the channel direction. Thereby, a continuous course of the impedance may be obtained.

According to an embodiment, the fluidic channel comprises channel portions that are disposed to be symmetric in a MEMS arrangement. Neighboring channel portions comprise inverse monotonous courses of scallop heights. This enables the monotonicity to be adjusted to a respective fluid stream direction.

According to an embodiment, the fluidic channel is a channel element of a serial channel arrangement extending across multiple MEMS layer arrangements. A respective channel element is disposed in a MEMS layer arrangement. A monotonously variable scallop height of a channel element, as a monotonous increase or a monotonous decrease, is the same or different from a neighboring channel element. This enables an efficient adjustment to a later application of the MEMS.

According to an embodiment, a multitude of scallop structures comprise a substantially matching scallop depth perpendicular to the channel direction.

In an alternative embodiment, a multitude of scallop structures is also disposed in the fluidic channel. The scallop structure, as a first scallop structure with a first scallop depth and as a second scallop structure of the multitude of scallop structures having a differing second scallop depth, is disposed perpendicular to the channel direction. This enables the fluidic flow to be adjusted within the fluidic channel.

According to an embodiment, the scallop structure is a first scallop structure, and the scallop arrangement comprises at least one second scallop structure disposed along a direction perpendicular to a main-side normal of the MEMS layer next to the first scallop structure. Geometries of the first scallop structure and the second scallop structure intersect to form at least one part of a common in-plane scallop-arrangement as an additional widening of the fluidic channel at this position. Through this, significantly larger fluidic channels and also an exposure of movable elements may be achieved.

According to an embodiment, a MEMS as described herein is formed to be a MEMS loudspeaker.

### BRIEF DESCRIPTION OF THE DRAWINGS

Embodiments of the present invention will be detailed subsequently referring to the appended drawings, in which:

FIG. 1 shows a schematic sectional side view of a MEMS according to an embodiment;

FIG. 2 shows a schematic sectional side view of a part of the MEMS in FIG. 1 in an enlarged representation;

FIG. 3 shows a representation of the part of the MEMS that is comparable to FIG. 2 for explaining embodiments;

FIG. 4 shows a schematic sectional side view of the part in FIG. 3, where scallops according to the invention are defined by the height and a radius of the scallop structures;

FIG. 5 shows a schematic sectional side view of a MEMS according to an embodiment, comprising a multitude of scallop structures in the fluidic channel;

FIG. 6 shows a schematic sectional side view of a MEMS according to an embodiment, in which the MEMS layer comprises at least two fluidic channels;

FIG. 7 shows a schematic top view of a MEMS according to an embodiment, in which a bottom layer, among other things, is illustrated;

FIG. 8a shows a schematic sectional side view of the bottom layer of a MEMS according to an embodiment having a multitude of scallop structures comprising a scallop height that varies monotonously, at least in portions, along the channel direction;

FIG. 8b shows a schematic sectional side view of a MEMS according to an embodiment, in which the scallop height is monotonously decreasing;

FIG. 9 shows a schematic sectional side view of a MEMS according to an embodiment that may be implemented to be a MEMS loudspeaker, for example;

FIG. 10 shows a schematic sectional side view of a MEMS according to an embodiment, in which a movable element comprises main sides that are configured to be mutually differing;

FIG. 11 shows a schematic sectional side view of another MEMS according to an embodiment; and

FIG. 12 shows a schematic flow diagram of a method according to an embodiment that may be used to manufacture a MEMS.

### DETAILED DESCRIPTION OF THE INVENTION

Before discussing embodiments of the present invention in detail below with reference to the drawings, it should be noted that elements, objects, and/or structures that are identical or functionally equivalent or that have equivalent effects are provided with the same reference numerals in the distinct figures so that the description of these elements presented in the distinct embodiments is interchangeable or may be applied among these elements.

Embodiments described below are described in connection with a multitude of details. However, embodiments may also be implemented without these detailed features. Furthermore, for a better understanding, embodiments are described using block circuit diagrams instead of a detail representation. Furthermore, details and/or features of individual embodiments may easily be combined with each other, unless explicitly stated to the contrary.

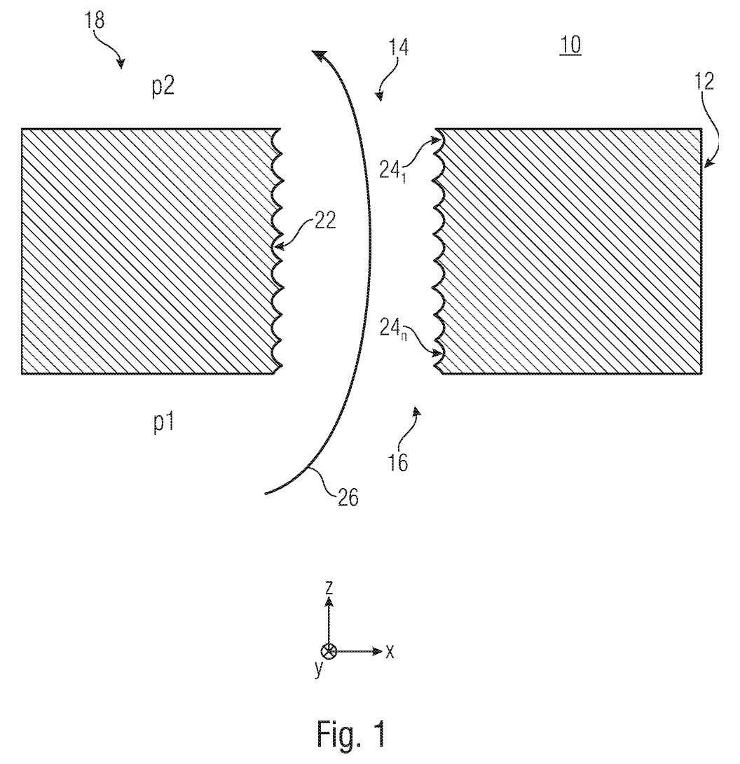

FIG. 1 shows a schematic sectional side view of a MEMS 10 according to an embodiment. The MEMS 10 comprises a MEMS layer 12 in which a fluidic channel 14 is disposed to provide a fluidic connection between a first channel side 16 and a second channel side 18. The MEMS layer 12 is not necessarily a single or integral layer, but may, as an alternative hereto, optionally include a higher number of interconnected layers. For example, electrically conductive layers and electrically non-conductive layers and/or electrically semi-conductive layers may be interconnected to form a layer arrangement of the MEMS layer 12. One or more layers of the MEMS 10 may include semiconductor-based materials, for example a silicon material, also including materials derived therefrom, such as silicon oxide and/or silicon nitride.

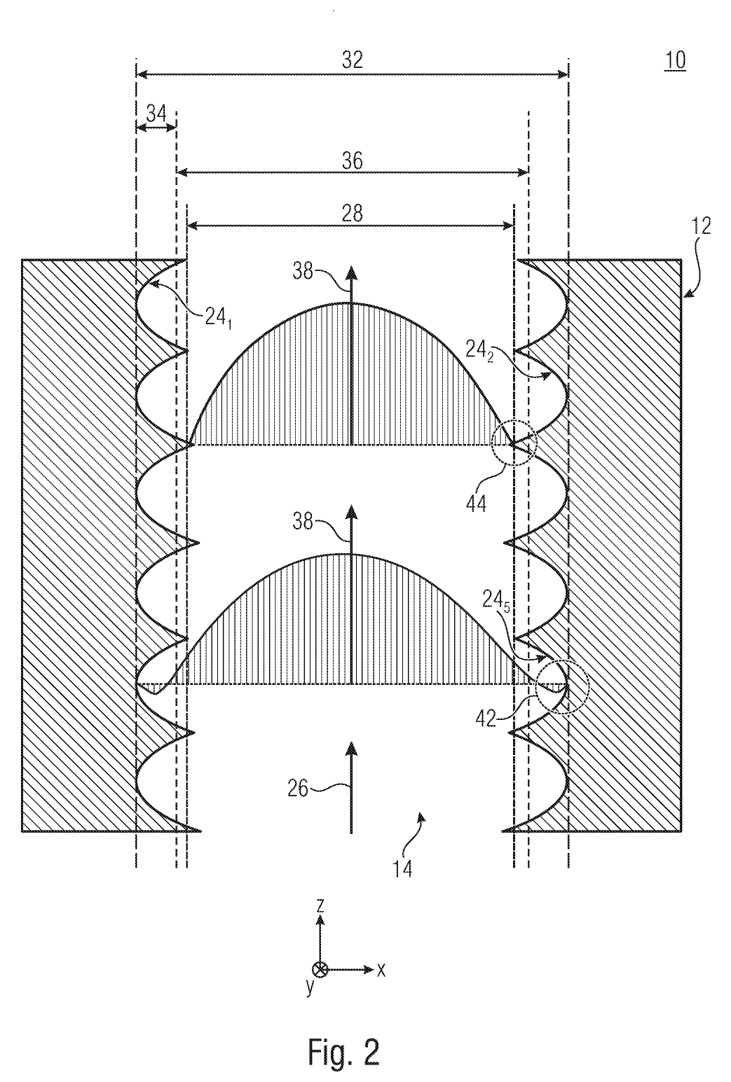

A side-wall structure 22 of the fluidic channel 14 comprises a scallop arrangement that comprises at least one scallop structure 24₁-24ₙ. Through the scallop structure or the scallop arrangement, an effective acoustic channel width of the fluidic channel 14 is enlarged when compared to a nominal channel width, as discussed with reference to FIG. 2. A channel width operative to transfer soundwaves is understood to be an effective acoustic channel width.

Through the fluidic channel 14, a fluid stream 26 may occur due to a pressure difference between the first channel side 16 having a pressure p1 and the second channel side 18 having a pressure p2. It is possible, but not necessary that a pressure p1 that is increased when compared to the pressure p2 is present at the first channel side 16. Thus, it is possible that at least one partial structure of the fluidic channel 14 is disposed to be movable, for example in an x/y plane or in parallel hereto, which may also be understood to be in plane. This may, for example, generate a pressure difference in the fluidic channel 14 due to the movement, which may cause the pressure at one of the two sides 16 or 18 to lose relevance.

In other words, FIG. 1 illustrates an embodiment of a channel 14 through which a fluid flows, such as in a MEMS-based loudspeaker. A wafer stack 12 separates two acoustic domains having a respective fluidic pressure p1 and p2. This wafer stack includes at least one channel or more channels connecting the two acoustic domains, while including walls structured with scallops. The pressure difference between the sides 16 and 18 of the wafer stack 12 generates a fluid flux or fluid stream 26 through the channel 14.

FIG. 2 shows a schematic sectional side view of a part of the MEMS 10 in an enlarged representation. FIG. 2 shows a nominal channel width of the fluidic channel 14 that may, for example, be obtained in the case that side walls of the fluidic channel 14 are configured to be even, without scallop structures 24. Furthermore, it illustrates an at least local maximum width 32 of the fluidic channel 14 that is obtained by enlarging the nominal channel width by a scallop depth 34 perpendicular to a channel depth z. By the scallop structures 24, an effective acoustic channel width 36 is enlarged when compared to the nominal channel width 36. This is illustrated exemplarily using a flow rate 38 which is zero, 0 or close to 0 at base points of the scallop structures 24, where the nominal channel width 28 is present in the fluidic channel 14, at the channel walls. With respect to the scallop structures, as illustrated using the scallop structure 24₅, in vertex areas of the scallop structure 24₅, a flow with a reversal in the flow direction may be provided, as can be seen from the change in sign of the flow rate 38.

This local reduction or reversal of the flux velocity may lead to a reduction of the total impedance when compared to the nominal channel width, thereby increasing the effective acoustic channel width 36 when compared to the nominal channel width 28.

Due to the scallop structure, a fluid profile of the fluidic channel 14 that is similar to a plane Poiseuille flow may be obtained at a base point or base area of a scallop structure 24₂ and a flow with a reversed flow direction may be obtained at the vertex areas 42.

Here, the scallop structures 24 may be generated in the MEMS layer 12 using a Bosch process. However, the same are not implemented arbitrarily, but such that the effect to enlarge the effective acoustic channel width according to the invention occurs.

In other words, FIG. 2 shows an embodiment in which, through the scallops, a velocity profile of the fluid that is different depending on the position is set.

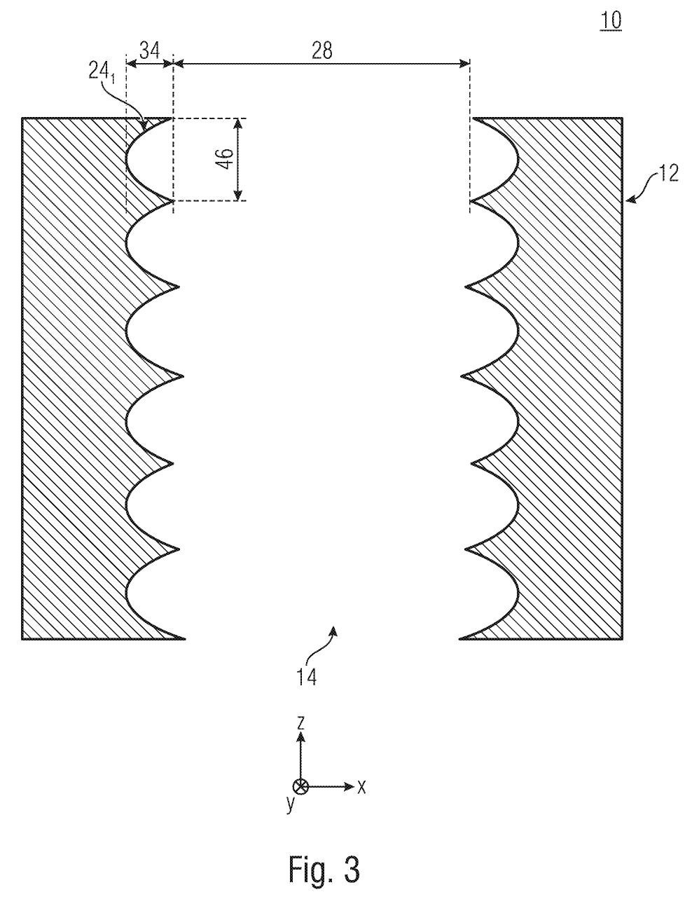

FIG. 3 shows a representation of the part of the MEMS 10 that is comparable to FIG. 2 for explaining embodiments. It illustrates the scallop depth 34 along with a scallop height 46 along the channel direction z. Embodiments relate to a MEMS in which the fluidic channel 14 extends along the channel direction z and at least one of the scallop structures 24 of the scallop arrangement extends along the channel direction z with a scallop height 46 of at least 200 nm, at least 300 nm or more, such as 350 nm or more. Alternatively or additionally, embodiments are advantageous in which the scallop depth perpendicular to the channel direction z comprises a value of at least 100 nm, at least 150 nm, or at least 200 nm when compared to the nominal channel width 28 in the MEMS layer 12.

In other words, FIG. 3 illustrates an embodiment in which the scallops are defined by the depth 34 and the height 46. Here, the depth is within an advantageous range between 100 nm and 10 µm, while the range between 0.5 µm and 2 µm is particularly advantageous. The height 46 is within a preferred range between 0.2 µm and 20 µm, whereas the range between 1.5 µm and 8 µm is particularly advantageous.

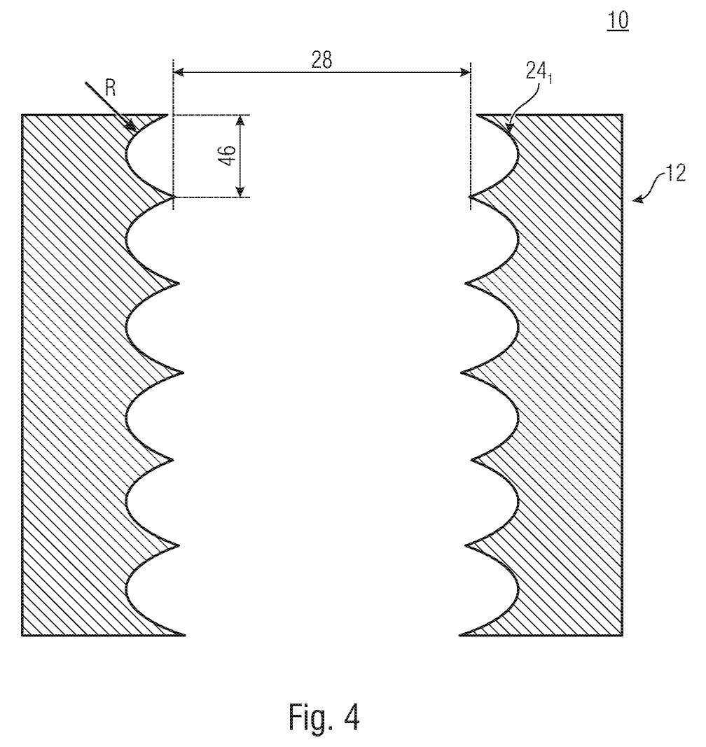

FIG. 4 shows a schematic sectional side view of the part of FIG. 3, whereas the scallops 24 are defined by the height 46 and a radius R of the scallop structures 24. In accordance with FIG. 3, the scallop height 46 is in a advantageous range between 0.2 µm and 20 µm and in a particularly advantageous range between 1.5 µm and 8 µm. According to this embodiment, the radius R is constant across the scallop structure, but may vary locally, for example to provide an elliptical structure. It is advantageous when the radius R at the base points and/or the vertex areas or at each position is greater than half of the height 46. The radius R may be in a advantageous range of at least half of the height (h/2) up to 200 µm, while the range of 3/5 h up to 3 h is particularly advantageous, h being the value of the height 46.

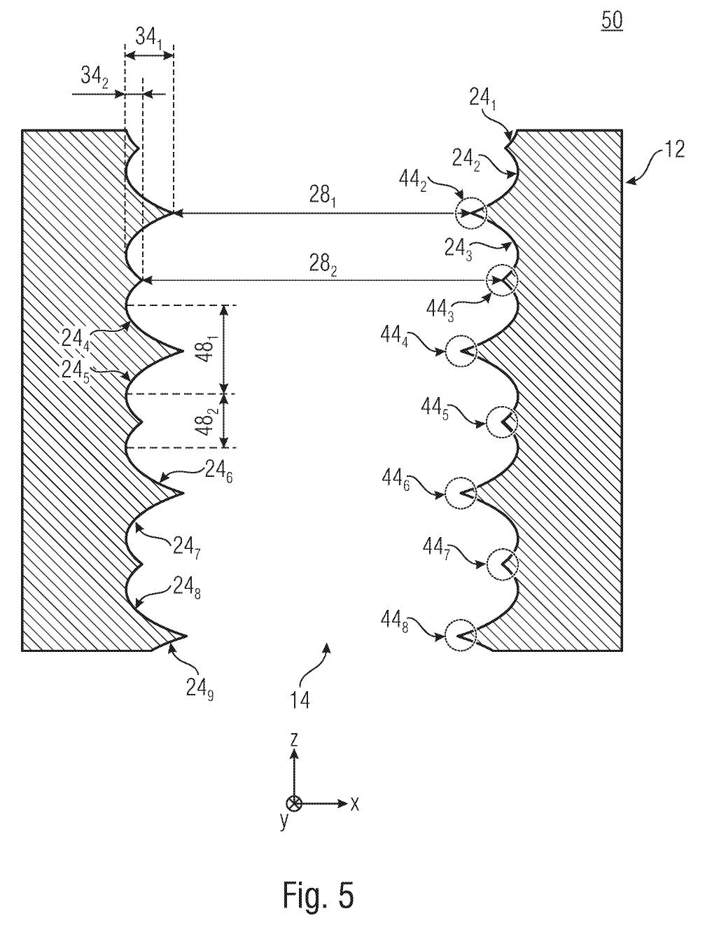

FIG. 5 shows a schematic sectional side view of a MEMS 50 according to an embodiment. The MEMS 50 comprises a multitude of scallop structures 24₁-24₉ in the fluidic channel 14. According to an embodiment, different pairs of neighboring scallops may comprise a mutually differing distance 48₁ or 48₂ between vertices of the scallop structures. Although only two mutually differing distances 48₁ and 48₂ are illustrated, additional different distances may also be implemented, i.e., at least three, at least four or more different distances. While the scallop structures 24₁-24₉ may be formed with a matching structure with respect to a scallop height, a scallop depth and/or a radius when compared to each other, it is also possible that, for example, two scallop arrangements are implemented shifted with respect to each other such that a shown shift in pairs is obtained. When using an additional third scallop arrangement that may also be periodic along the channel direction z, it is easily possible to obtain a third distance.

As illustrated in FIG. 5, the scallop structures 24₁, 24₃, 24₅, 24₇ and 24₉, for example, form a first scallop arrangement, and the scallop structures 24₂, 24₄, 24₆ and 24₈ form a second scallop arrangement. By shifting the second scallop arrangement with respect to the first scallop arrangement along a negative z direction, a first distance 48₁ between two neighboring scallop structures 24₄ and 24₅ may be increased, while reducing another neighboring distance between the scallop structures 24₅ and 24₆. In a specific embodiment of the MEMS 50, a sum of distances 48₁ and 48₂ of any three neighboring scallop structures may be constant across the channel depth 14, such as in the case of two scallop arrangements.

The multitude of scallop structures of the MEMS 50 may comprise a first pair 24₄, 24₅ of scallop structures having the first distance 48₁ and a second pair 24₅/24₆ of neighboring scallop structures having a differing distance 48₂ from vertices of the scallop structures.

This may also result in a mutually different position of base points or base areas 44 along a channel width in parallel to the x direction of the fluidic channel when viewing the course of the fluidic channel along the z direction. This is illustrated exemplarily for a first channel width 28₁ at a base area 44₂ and a differing channel width 28₂ at a base area 44₃.

In other words, FIG. 5 shows another embodiment in which the scallops are shifted with respect to each other such that at least two different channel widths 28₁ and 28₂ defined by the scallop peaks are created. Furthermore, this creates at least two different height distances 48₁ and 48₂ of the scallop bases.

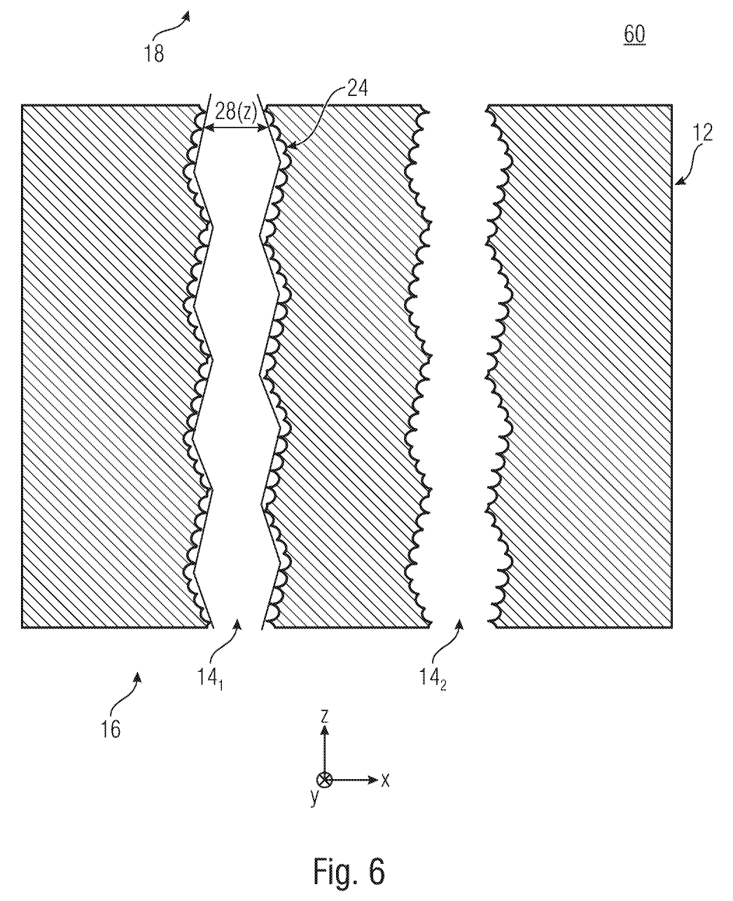

FIG. 6 shows a schematic sectional side view of a MEMS 60 according to an embodiment in which the MEMS layer 12 comprises at least two fluidic channels 14₁ and 14₂ to connect the first channel side 16 with the second channel side 18. Thus, it is possible, but not necessary for the fluidic channels 14₁ and 14₂ to comprise a matching first channel side 16 and/or a matching second channel side 18.

Independent of the number of fluidic channels, which may easily be 1, the nominal channel widths of the fluidic channels 14₁ and 14₂ are variable over a course of the fluidic channels 14₁ and 14₂ along the z direction. This may result in a nominal channel width 28 that is dependent on the position along the z direction so that a channel nominal width 28(z) may be obtained as a function of the position along z. In the embodiment of the MEMS 60, the nominal channel width 28 is periodically variable over the course of the fluidic channel 14₁. Scallop structures having constant or mutually differing depths and/or heights may be modulated onto this periodic change.

In other words, FIG. 6 shows a cross-section of an exemplary fluidic channel. The channel has a serrated shape with scallops at the walls.

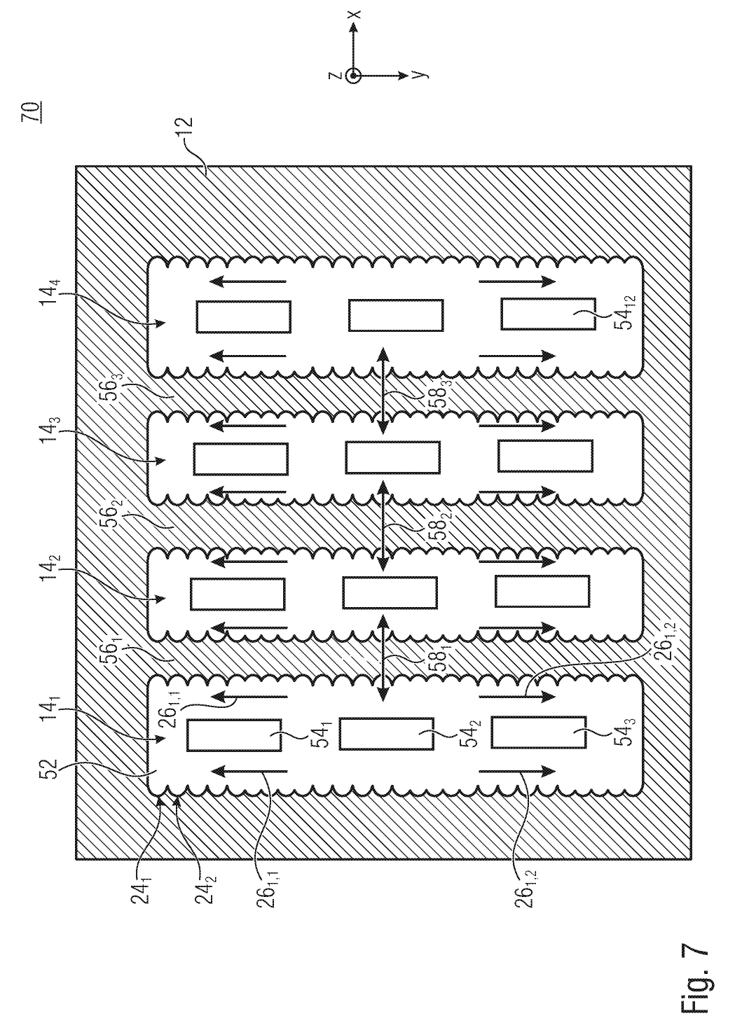

FIG. 7 shows a schematic top view of a MEMS 70 according to an embodiment. Here, several embodiments that may be implemented independent of each other can be seen. In addition to the MEMS layer 12, a bottom layer 52 is illustrated exemplarily, which may, but does not have to represent a last layer along a negative z direction. This layer may comprise openings 54₁ to 54₁₂, for example to bend the fluidic channels 14₁ to 14₄ with the first channel side or the second channel side.

An advantageous implementation, as shown in FIG. 7, is the configuration as MEMS in which the scallop structure 24₁ is disposed next to another scallop structure 24₂ along a direction perpendicular to a main-side normal of the MEMS layer 12, running, for example, in parallel to the z direction. The geometries of the two scallop structures 24₁ and 24₂ intersect each other and form at least one part of a common in-plane scallop arrangement. While, for example, in MEMS 10, neighboring scallop structures are disposed to be neighboring each other along the channel direction z, whereas a respective scallop structure 24 may be manufactured by a single etching process, the scallop structures 24₁ and 24₂ of the MEMS 70 are disposed in plane next to each other, which may lead to an increase of the channel cross-section. This does not exclude additionally disposing further scallop structures along the channel direction z, on the contrary, this is explicitly provided for by embodiments.

Independent of this, at least parts of the MEMS layer 12 may be formed to be a movable element 56₁, 56₂ and/or 56₃ that is disposed in parallel to the MEMS plane. Such a movable element may be configured to interact with a neighboring fluidic channel 14₁ to 14₄ to cause a fluidic flux 26_{i,j}, wherein a movement of the movable element 56₁ to 56₃ and a movement of the fluid through the fluidic channel 14₁ to 14₃ are causally related. Here, the indices i and j of the fluid streams 26_{i,j} denote the fluidic channel, wherein i = 1 ... 4 and j is a fluid sub-stream within the fluidic channel 14. A reason for this is, for example, that a center area of the respective movable element 56₁, 56₂ and 56₃ is deformed or deflected more strongly than a boundary area and that, for example, a central tapering of the fluidic channel 14 in the x/y plane may lead to an outward displacement of fluid along the opposite directions.

Deflection directions 58₁, 58₂ and 58₃ of the movable elements 56₁, 56₂ and 56₃, respectively, may be in parallel to each other, and the respective movable elements may move in the sense of a back-and-forth movement, wherein a manner of actuation may be arbitrary. If the MEMS 70 is configured to be a loudspeaker, for example, active forces may be generated by electrostatic, piezoelectric, magnetic and/or thermal forces. It is also possible to provide, such as in a microphone configuration, that the fluid triggers a movement of the movable element, which is then detected.

In the MEMS 70, in both cases, a fluidic channel 14₁ to 14₄ is formed at least partially by a side-wall structure of the movable element 56₁ to 56₃ that is disposed perpendicular to the MEMS plane, such as along the z direction.

In other words, FIG. 5 shows a top view of a MEMS member. The fins 56 comprise in-plane scallops. This leads to a reduction of the acoustic attenuation along the fins.

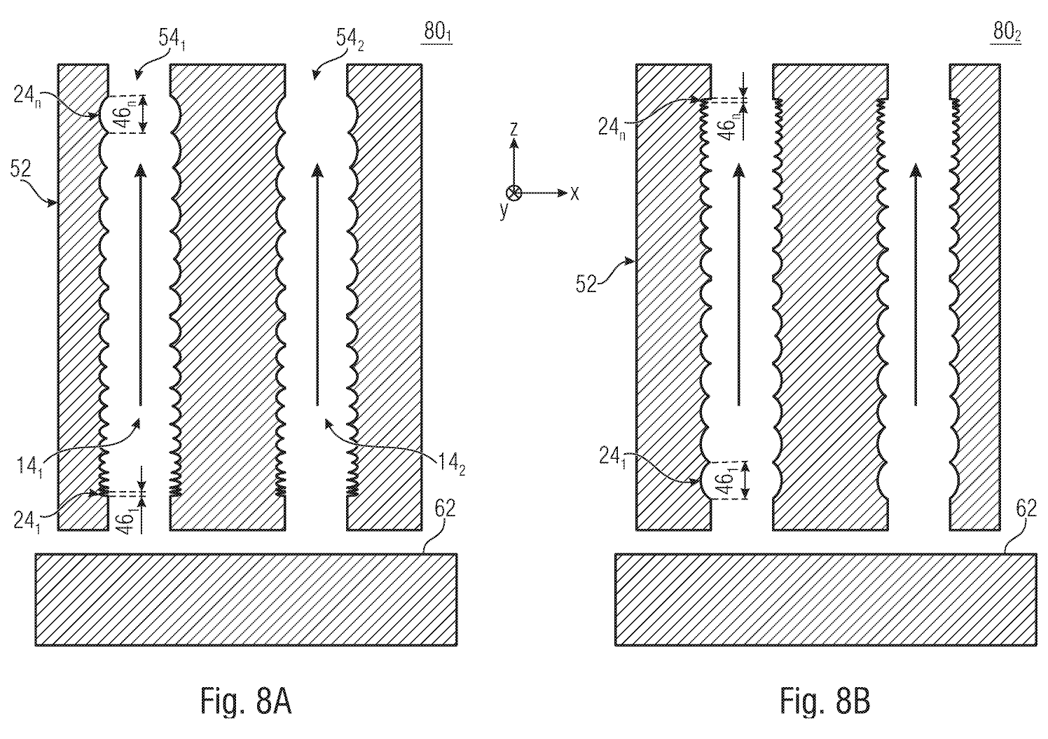

FIG. 8a shows a schematic sectional side view of the bottom layer 52 of a MEMS 80₁ according to an embodiment. The bottom layer 52 may, for example, include the MEMS layer 12 of the MEMS 10. At least one additional MEMS layer arrangement 62 having electrically passive and/or electrically active properties and/or mechanically passive and/or mechanically active properties may provide one part of the MEMS 80₁. The scallop arrangement includes a multitude of scallop structures for each fluidic channel 14₁ and 14₂, wherein, according to embodiments, one fluidic channel or more than two fluidic channels may already be provided. The fluidic channel 14₁ and the fluidic channel 14₂ extend along the channel direction z, which, however, does not necessarily have to be disposed perpendicular to the x/y plane. FIG. 8a shows that a multitude of scallop structures 24₁ to 24ₙ comprise a scallop height 46₁ to 46ₙ that varies monotonously, at least in portions, along the channel direction. In case of the MEMS 80₁, the scallop height 46₁ to 46ₙ increases monotonously.

FIG. 8b shows a schematic sectional side view of a MEMS 80₂ to which the details of the MEMS 80₁ also apply, whereas, here, the scallop height decreases monotonously.

In other words, FIG. 8a and 8b each show a cross-section of cap-bottom wafer. The height 46 of the individual scallops increases as the height/depth of the channel increases. The channel width may remain the same.

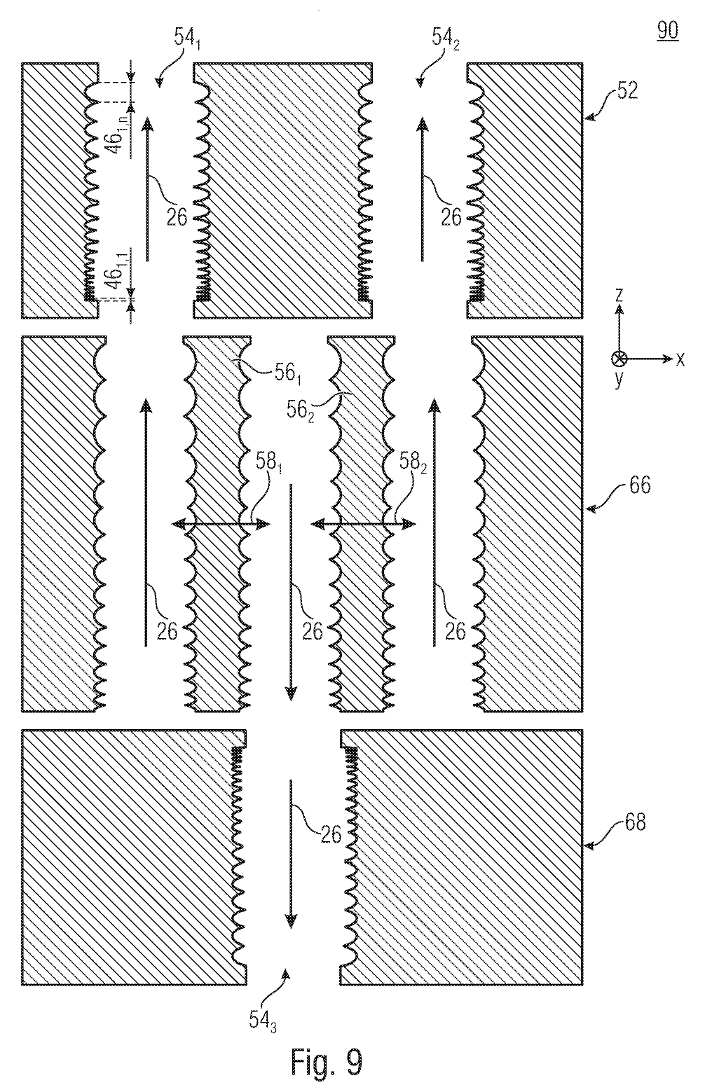

FIG. 9 shows a schematic sectional side view of a MEMS 90 according to an embodiment that may, for example, be implemented to be a MEMS loudspeaker.

By way of example, the layer 52 of the MEMS 80₁ of FIG. 8 is illustrated, which may, here, exemplarily serve as a cap wafer. Another MEMS layer or layer arrangement 66 may, for example, include a device wafer having one or more layers, wherein, here, for example, movable elements 56₁ and 56₂ may be disposed. The MEMS 90 may comprise another MEMS layer arrangement 68 that may, for example, be used as a bottom wafer, wherein such terms may be interchanged arbitrarily as the orientation of the MEMS 90 changes.

A movement of the movable elements 56₁ and 56₂ may lead to sound pressure waves that alternately lead through the openings 54₁ and 54₂, on the one hand, and 54₃, on the other hand. Thus, for example, a possibly synchronous movement of the movable elements 56₁ and 56₂ away from each other may lead to sound pressure waves through the openings 54₁ and 54₂, and a synchronous movement of the movable elements 56₁ and 56₂ towards each other may lead to sound pressure waves out of the opening 54₃.

The fluid stream 26 may comprise locally differing directions. FIG. 9 illustrates that the scallop arrangement may be mutually differing in different layers. Thus, starting from the MEMS layer arrangement 66 towards the outside along a positive z direction in the MEMS layer 52, an expansion in the form of a monotonous increase of the scallop heights 46_{1,1} to 46_{1,n} may be implemented. In the MEMS layer arrangement 68, this may be inverted with respect to the direction z in space so that an optional monotonous increase of the scallop heights is also implemented towards the outside along the negative z direction.

Independent of this, a scallop height in the MEMS layer arrangement 66 along the z direction may be constant, variable, or monotonously variable or strictly monotonously variable.

In other words, FIG. 9 shows a cross-section of the cap wafer, device wafer, and bottom wafer. The height of the individual scallops increases as the height in the cap wafer and the device wafer increases. In the bottom wafer, the height h of the scallops increases as the depth increases.

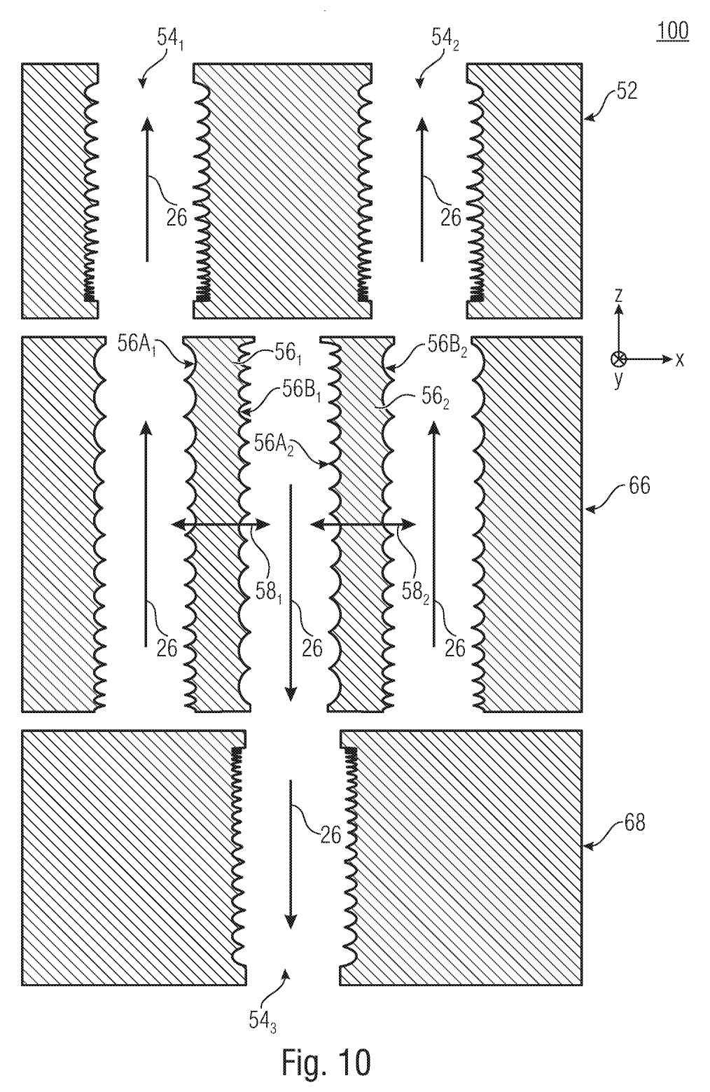

FIG. 10 shows a schematic sectional side view of a MEMS 100 according to an embodiment. The MEMS 100 may be formed in correspondence with the MEMS 90, but may deviate in that, for example, the movable elements 56₁ and 56₂ are formed with mutually differing main sides with respect to the arrangement and the configuration of the scallop structures. A respective main side 56A₁ and 56A₂, respectively, and an opposite second main side 56B₁ and 56B₂, respectively, of each of the movable elements 56₁ and 56₂ may be part of a different fluidic channel, as it also applies to the MEMS 90. However, while, for example, a matching monotonous increase or decrease of the scallop heights is disposed on the different main sides of the MEMS 90, the different main sides of a movable element 56₁ and 56₂ comprise a mutually differing arrangement. Thus, for example, on the main side 56A₁ and on the main side 56B₂ along the z direction, an expansion of the scallop heights, in particular a monotonous increase, is implemented, whereas on the respective opposite main sides 56B₁ and 56A₂ along the z direction, a monotonously decreasing scallop height is disposed. This may enable an adjustment to the respective flux direction of the fluid stream 16. A mutually differing embodiment on the main sides may, for example, be achieved by individually etching the respective fluidic channel in a MEMS layer 52, 66 and 68, which may autonomously and independently of each other provide a MEMS layer 12.

In other words, FIG. 10 illustrates a cross-section of the cap wafer, device wafer, and bottom wafer. The height of the individual scallops increases as the height in the cap wafer increases. In the bottom wafer, the height of the scallops increases as the depth increases. In the channels of the device wafer 66, the height of the scallops increases in two channels as the height increases and in one channel as the depth increases.

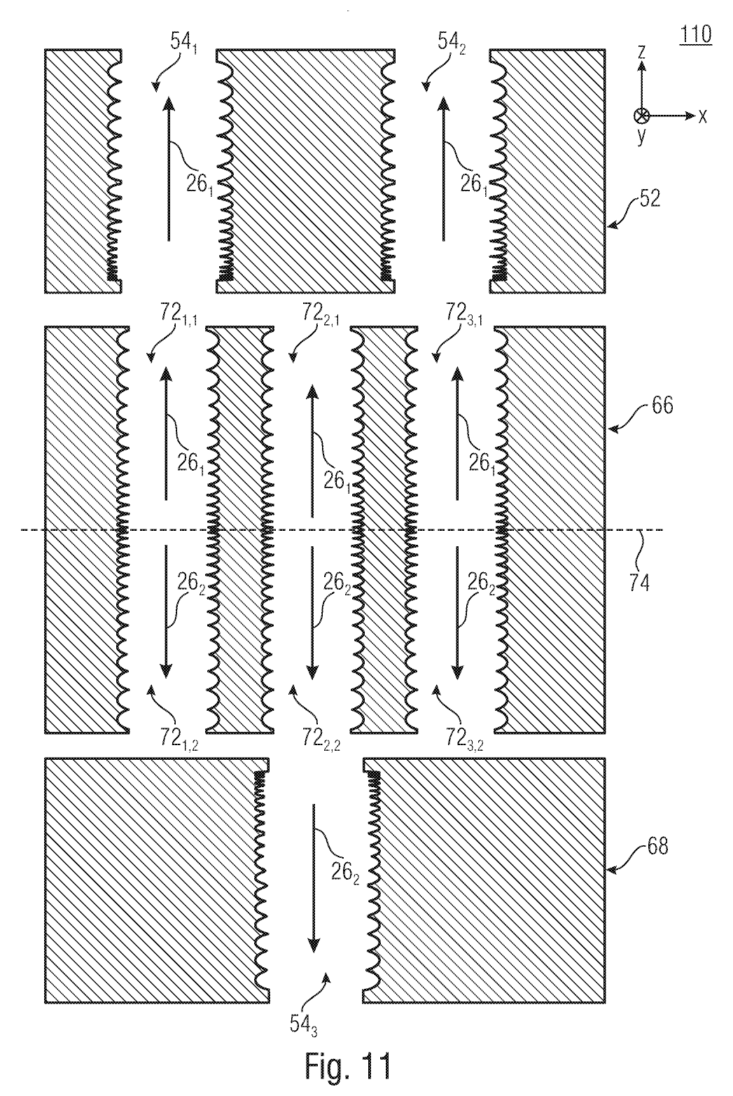

FIG. 11 shows a schematic sectional side view of a MEMS 110 according to an embodiment. The MEMS 110 may at least partially be formed in accordance with the MEMS 90 and 100. In deviation from the MEMS 90 and the MEMS 100, the MEMS layer 66, such as the device wafer, is formed. In the fluidic channels, this may include respective channel portions 72_{1,1} and 72_{1,2} of a first fluidic channel, 72_{2,1} and 72_{2,2} of a second fluidic channel, and 72_{3,1} and 72_{3,2} of a third fluidic channel of the MEMS layer 66. The respective channel portions may be formed symmetrically with respect to a symmetry plane 74 and may, for example starting from the symmetry plane 74, provide an increasing scallop height along a positive z direction and also provide an increasing scallop height along a negative z direction. This configuration may also easily be inverted. Although the channel portions 72 of the three different fluidic channels in the MEMS layer 66 are illustrated such that the same are formed to be equal or identical, the fluidic channels of one or more MEMS layers may also be formed individually and mutually deviating, which also applies to the MEMS 90 and 100.

Neighboring channel portions 72_{1,1} and 72_{1,2}, 72_{2,1} and 72_{2,2} as well as 72_{3,1} and 72_{3,2} may comprise inverted monotonous courses of the scallop heights.

It is illustrated in the MEMS 90, 100 and 110 that a fluidic channel over at least one MEMS layer 52, 66 and 68 may be formed with one channel element each of a serial channel arrangement over the different MEMS layers 52, 66 and 68. The channel arrangement may, therefore, extend across multiple MEMS layer arrangements or MEMS layers. A respective channel element in a MEMS layer arrangement may comprise a constant or variable, for example a monotonously variable, scallop height of a channel element as a monotonous increase or a monotonous decrease that is equal to or different from a neighboring channel element in another MEMS layer.

In a possible embodiment illustrated in FIGS. 9, 10 and 11, a multitude of scallop structures of a channel portion or a fluidic channel may comprise a substantially matching scallop depth perpendicular to the channel direction z.

As an alternative to a matching scallop depth, mutually differing scallop depths may also be provided in a multitude of scallop structures.

In other words, FIG. 11 shows a cross-section of the cap wafer, device wafer, and bottom wafer. In the device wafer, the height of the individual scallops increases starting from half the channel height as the height and depth increase.

Embodiments of the present invention relate to MEMS, for example as MEMS that are part of a MEMS loudspeaker. Some embodiments relate to MEMS loudspeakers comprising a MEMS as described herein. Some embodiments are characterized by scallops on the walls of a channel through which a fluid flows, the scallops comprising a depth 34 in a range between 0.1 µm and 10 µm, wherein the range between 0.5 and 2 µm may be particularly advantageous. Alternatively or additionally, a height 46 between 0.2 µm and 20 µm is provided, wherein the range between 1.5 µm and 8 µm is particularly advantageous.

Some embodiments are characterized by scallops having a radius R being greater than half of the height, however up to 200 µm at the maximum, wherein the range between 3/5 h and 3 h is particularly advantageous. The parameter h stands for the scallop height 46.

Some embodiments are characterized by scallops that are shifted with respect to each other so that at least two different height distances of the scallop bases and at least two different channel widths defined by scallop peaks are created, as described in the context of FIG. 5.

Some embodiments are characterized by scallops whose size varies across the depth of the channel.

Some embodiments are characterized by scallops on the walls of a channel through which a fluid flows and that has a serrated shape, as described in the context of FIG. 6, for example.

Some embodiments are characterized by fins having in-plane scallops, as described in FIG. 7, for example.

Some embodiments are characterized by the height h and the height 46 of the individual scallops, respectively, that increases or decreases as the height and/or depth of a channel through which a fluid flows increases.

Some embodiments are characterized by the height h, the height 46, of the individual scallops that increases in the cap wafer and device wafer as the height increases and that increases in the bottom wafer as the depth increases, as described in the context of FIG. 9.

Some embodiments are characterized by the height h and the height 46 of the individual scallops, respectively, that increases in the cap wafer as the height increases and that increases in the bottom wafer as the depth increases and that increases in the channels of the device wafer in at least one channel as the height increases and in at least one other channel as the depth increases, as described in the context of FIG. 10.

Some embodiments are characterized by the height h and the height 46 of the individual scallops, respectively, that increases or decreases, starting from half the channel height, for example in the device wafer as the height increases and the depth increases, as described in the context of FIG. 11.

Embodiments of the present invention relate to micro-electromechanical systems, MEMS. Using the Bosch method, channels and/or openings may be formed in a semiconductor substrate. In this method, the etching process and the switch-off process are repeated. In so doing, wavy side faces are formed at the opening that is created, a process which is also known as scalloping, wherein the resulting structures are referred to as scallops. While conventional technology is directed towards minimizing this scalloping effect in order to obtain walls that are as smooth as possible, embodiments aim at purposely using this scalloping effect, since smooth walls in a channel through which a fluid flows in a MEMS-based loudspeaker lead to an increase of acoustic impedances that can be reduced according to the invention. The aim of MEMS loudspeakers as described herein is to reduce the acoustic impedances. The same mechanisms may also be used in MEMS microphones or other MEMS for transporting fluid.

The object of some embodiments is to reduce the acoustic impedances in a channel of a MEMS loudspeaker through which a fluid flows. Such an object is solved by purposely enlarging the depth and the height of the scallops in a channel of a MEMS loudspeaker through which a fluid flows. At the narrowest position of the channel, the nominal channel width, a fluid profile that is similar to a plane Poiseuille flow may be created while at the widest position of the channel, a channel width with scallops, a flow with a reversal in the flow direction may be created in the scallop base. Here, the point of inflection of the flow is between the plane of the scallop peaks (nominal channel width) and the plane of the scallop bases (channel width with scallops). Through this local change in the flow profile, the acoustically effective channel width is greater than the nominal channel width and, thus, the impedance of the channel with scallops is reduced when compared to a smooth channel with the same nominal channel width, which is advantageous.

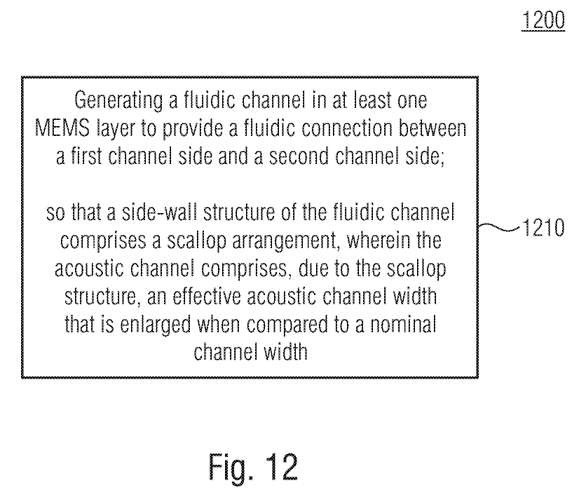

FIG. 12 shows a schematic flow diagram of a method 1200 according to an embodiment that may be used to manufacture a MEMS, such as a MEMS as described herein. A step 1210 includes generating a fluidic channel in at least one MEMS layer to provide a fluidic connection between a first channel side and a second channel side so that a side-wall structure of the fluidic channel comprises a scallop arrangement, wherein the acoustic channel comprises an effective acoustic channel width due to the scallop structure, the acoustic channel width being enlarged when compared to a nominal channel width.

Such an enlargement is not achieved by the scallops in the conventional technology that are as small as possible, on the contrary, it is even avoided there.

Although some aspects have been described in the context of an apparatus, it is understood that these aspects also represent a description of the corresponding method so that a block or component of an apparatus is also to be understood to be a corresponding method step or a feature of a method step. In analogy, aspects described in connection with or as a method step also represent a description of a corresponding block or detail or feature of a corresponding apparatus.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A MEMS with a fluidic channel in at least one MEMS layer configured to provide a fluidic connection between a first channel side and a second channel side;
wherein a side-wall structure of the fluidic channel comprises a scallop arrangement, wherein the fluidic channel comprises, due to the scallop arrangement, an effective acoustic channel width that is enlarged when compared to a nominal channel width.

2. The MEMS according to claim 1, wherein the nominal channel width describes a state of side walls of the fluidic channel to be even, without scallop structures.

3. The MEMS according to claim 1, wherein a fluidic impedance of the fluidic channel is reduced when compared to a fluidic channel with a constant channel width corresponding to the nominal channel width.

4. The MEMS according to claim 1, wherein the fluidic channel extends along a channel direction and at least one scallop structure of the scallop arrangement extends along the channel direction with a scallop height of at least 200 nm and/or extends perpendicular to the channel direction with a scallop depth of at least 100 nm when compared to the nominal channel width in the MEMS layer.

5. The MEMS according to claim 1 comprising an in-plane movable element that is disposed in parallel to a MEMS plane and configured to interact with a fluid in order to cause a fluidic flow in the fluidic channel, wherein a movement of the movable element and a movement of the fluid through the fluidic channel are causally related.

6. The MEMS according to claim 5, wherein the fluidic channel is partially formed by a side-wall structure of the movable element that is disposed perpendicular to the MEMS plane.

7. The MEMS according to claim 5, wherein the fluidic channel is a first fluidic channel; and the movable element comprises a first main side being part of the first fluidic channel; and an opposite second main side being part of a second fluidic channel; wherein, along a corresponding direction in parallel to the first fluidic channel on the first main side, a monotonously increasing scallop height of a first multitude of scallop structures is disposed and a monotonously decreasing scallop height of a second multitude of scallop structures is disposed on the second main side.

8. The MEMS according to claim 1, wherein the fluidic channel is configured for providing a fluid profile at base point areas of the scallop structure similar to a plane Poiseuille flow and provides, at vertex areas of the scallop structure, a flow with a reversed flow direction.

9. The MEMS according to claim 1, wherein the nominal channel width is variable over a course of the fluidic channel.

10. The MEMS according to claim 9, wherein the nominal channel width is periodically variable over the course of the fluidic channel.

11. The MEMS according to claim 1 comprising a multitude of scallop structures, wherein a first pair of neighboring scallop structures comprises a different distance from vertices of the scallop structures than a second pair of neighboring scallop structures.

12. The MEMS according to claim 11, wherein the multitude of scallop structures comprise, along a course of the fluidic channel, mutually differing positions of base points along a channel width of the fluidic channel.

13. The MEMS according to claim 1, wherein the scallop arrangement comprises a multitude of scallop structures, wherein the fluidic channel extends along a channel direction and the multitude of scallop structures comprise a scallop height that varies monotonously, at least in portions, along the channel direction.

14. The MEMS according to claim 13, wherein the fluidic channel comprises channel portions that are disposed to be symmetric in a MEMS arrangement; and neighboring channel portions comprise inverse monotonous courses of the scallop heights.

15. The MEMS according to claim 14, wherein the fluidic channel is a channel element of a serial channel arrangement extending across multiple MEMS layer arrangements, wherein a respective channel element is disposed in a MEMS layer arrangement and a monotonously variable scallop height of a channel element, as a monotonous increase or a monotonous decrease, is the same or different from a neighboring channel element.

16. The MEMS according to claim 13, wherein the multitude of scallop structures comprise a substantially corresponding scallop depth perpendicular to the channel direction.

17. The MEMS according to claim 1, wherein a multitude of scallop structures are disposed in the fluidic channel and the scallop structure, as a first scallop structure with a first scallop depth and a second scallop structure of the multitude of scallop structures with a differing second scallop depth, is disposed perpendicular to the channel direction.

18. The MEMS according to claim 1, wherein the scallop structure is a first scallop structure and the scallop arrangement comprises at least one second scallop structure disposed along a direction perpendicular to a main-side normal of the MEMS layer next to the first scallop structure, wherein geometries of the first scallop structure and the second scallop structure intersect and form at least one part of a common in-plane scallop arrangement.

19. The MEMS according to claim 1 formed to be a MEMS loudspeaker.

20. A method for manufacturing a MEMS, comprising:
generating a fluidic channel in at least one MEMS layer to provide a fluidic connection between a first channel side and a second channel side;
so that a side-wall structure of the fluidic channel comprises a scallop arrangement, wherein the fluidic channel comprises, due to the scallop arrangement, an effective acoustic channel width that is enlarged when compared to a nominal channel width.
